(19) United States
(12) Patent Application Publication
(10) Pub. No.: US 2024/0209290 A1
(43) Pub. Date: Jun. 27, 2024

(54) Semiconductor Wafer Cleaning Solution and Cleaning Method Thereof

(71) Applicant: Star Tracking Material Co. Ltd., Taoyuan City (TW)

(72) Inventors: CHUN-LI CHOU, New Taipei City (TW); HSUAN-I CHOU, New Taipei City (TW)

(21) Appl. No.: 18/392,825

(22) Filed: Dec. 21, 2023

(30) Foreign Application Priority Data
Dec. 21, 2022 (TW) 111149236

(51) Int. Cl. C11D 3/33; C11D 3/28; C11D 3/30; C11D 3/34

(52) U.S. Cl. CPC C11D 3/33; C11D 3/28; C11D 3/30; C11D 3/349; H01L 21/02063

(57) ABSTRACT

A semiconductor wafer cleaning solution may include at least a first agent, a second agent, and water. The first agent is configured to chelate residual metals on the semiconductor wafer. The second agent has a solubility of 35 g/100 ml to 45 g/100 ml in water with a pH-value greater than 6 and less than 7 at 20° C., and has an acid dissociation constant between 7 and 8 at 20° C. The pH-value of the cleaning solution is maintained in the range of 6.5 to 8.8 at 20° C. to 70° C. In the cleaning solution, the metal chelating ability of the first agent is greater than that of the second agent.

### FILED OF THE INVENTION

The present invention relates to cleaning of semiconductor wafers, in particular to a semiconductor wafer cleaning solution and a cleaning method thereof.

### BACKGROUND OF THE INVENTION

In current semiconductor circuits, there are multiple layers of metal interconnects, which constitute a 3D wire structure. These metal interconnects are composed of conductive metal circuits surrounded by insulating dielectric materials. With the improvement of circuit integration, to reduce the parasitic capacitance between metal interconnects and reduce the resistance of wires, materials with a low k dielectric constant, such as SiOC, and low-resistance metal materials, such as copper, are generally used to increase the speed of conduction to further improve the performance of integrated circuits.

For multi-layer metal interconnects in the early stage, the wiring patterns are made by etching the metal layers, and then the dielectric layer is filled. However, when the metal material is converted from aluminum to copper with lower resistivity, it is difficult to pattern and etch copper directly, so a new process has been developed. According to the process, etching is performed on the dielectric layer to form a pattern and then metal filling is carried out, which is called damascene technology. Before the metal filling, the process of forming not only a single-layer wiring pattern, but also a via between the layers on the dielectric layer, is called a dual damascene structure. Generally, after the patterning of the dual damascene structure is completed, a metal masking layer needs to be deposited. For example, TiN is usually used in the aluminum process, and TaN is usually used in the copper process. Metal deposition and chemical mechanical polishing processes are then performed.

Various suitable materials can be used in combination in the dual damascene process, and an opening is etched in the dielectric layer by optical lithography to expose the underlying metal connection layer, such as copper, aluminum, tungsten, cobalt, and tantalum. However, various etching techniques used in the dual damascene process will inevitably produce various unwanted metal residues or various inorganic or organic residues on the top or inner wall of the dual damascene opening. These unwanted residues interfere with subsequent process steps and have adverse effects on the final integrated circuit. Therefore, a cleaning step is required to remove the unwanted residues before filling the opening with metal.

### SUMMARY OF THE INVENTION

For cleaning after an etching process, a cleaning solution in the prior art is usually discharged and discarded after only cleaning one wafer and cannot be reused.

According to the present invention, further studies show that the conventional cleaning solution has a problem that the chelating ability on metal is quickly reduced after the cleaning solution is used once, so it is difficult to reuse the cleaning solution. The conventional cleaning solution also has the problem of improperly damaging the surface of a dielectric layer or the surface of a metal layer. If a cleaning solution with relatively mild oxidizing force is changed, the oxidizing force of the cleaning solution is obviously reduced after being used once, and it is also difficult to reuse the cleaning solution.

In view of this, the present invention provides a semiconductor wafer cleaning solution and a cleaning method thereof, which can effectively remove residual metal or other residues after etching, such as plasma etching, and meanwhile, the exposed surface of the dielectric layer or the surface of the metal layer is not damaged in yield, such as electrical short circuit or high resistance.

On the other hand, the cleaning solution in the present invention can be repeatedly used for cleaning a plurality of semiconductor wafers for a long time, so that used chemicals can be greatly reduced, and the consumption of the cleaning solution can also be greatly reduced.

Further technical features and advantages of the present invention will be described in the following description of exemplary embodiments and the appended claims of the present invention.

### BRIEF DESCRIPTION OF THE DRAWINGS

The present invention will be illustrated in more detail below on the basis of exemplary embodiments shown in the accompanying drawings, wherein:

FIG. 1 is a schematic cross-sectional view of a process according to an embodiment of the present invention, which shows residues generated after forming a damascene opening.

### DETAILED DESCRIPTION OF THE INVENTION

The semiconductor wafer cleaning solution and a cleaning method thereof will be described in detail below. It should be understood that multiple different embodiments or examples provided below are for implementing different aspects of the present disclosure. These different embodiments or examples are only for illustration and not for limiting the present invention. Those skilled in the art can associate other advantages of the present invention based on the contents disclosed herein, so that the present invention can also be implemented or applied in different specific embodiments. Those skilled in the art can modify and/or change the specific embodiments based on different implementations and applications to implement the present invention without departing from its spirit and scope.

The present invention provides a cleaning solution for removing residues, especially residues after etching, on the surface of a semiconductor wafer. The cleaning solution can simultaneously remove metal residues or other organic and inorganic residues and can keep the integrity of a metal layer material and a Low-k dielectric material. Besides, the present invention also provides a method for removing the residues on the surface of the semiconductor wafer; and the method is carried out by cleaning one or more semiconductor wafers which are not cleaned by using the solution which has been used for cleaning the semiconductor wafer.

The “residues” in the present invention refer to various unnecessary trace substances left on the surface of the semiconductor wafer after a dry plasma etching process or a wet etching process. The residues can be naturally various metals (such as copper, aluminum, tungsten, cobalt and tantalum), organic matters (such as organic metals and organic silicon), or inorganic matters (such as silicon-containing materials, titanium-containing materials, nitrogen-containing materials, oxygen-containing materials, copper oxides, aluminum oxides, tungsten oxides, cobalt oxides, tantalum oxides, reaction products of etching gases and semiconductor materials (like various halides)) and the like or combinations thereof.

A “Low-k dielectric material” in the present invention refers to any material used as a dielectric material in a layered semiconductor wafer, and has a dielectric constant less than about 3.5. The Low-k dielectric material preferably comprises a low-polarity material, such as a silicon-containing organic polymer, a silicon-containing organic/inorganic mixed material, organosilicate glass (OSG), TEOS, fluorinated silicate glass (FSG), silicon dioxide, a carbon-doped oxide (such as CDO, SiCOH, or SiOC), etc.

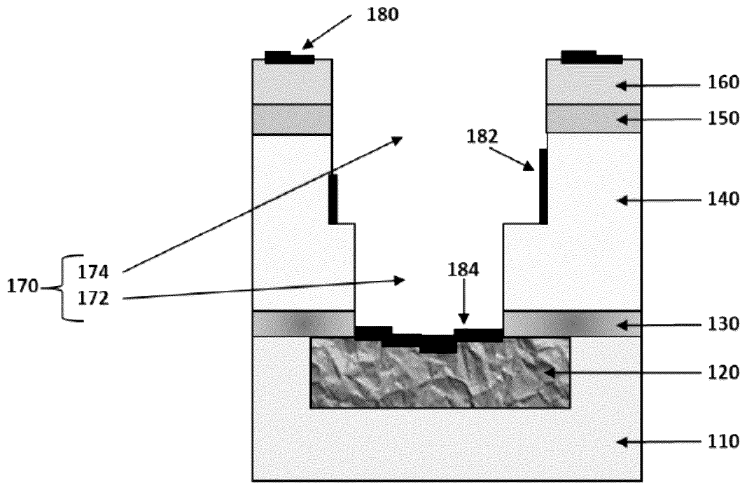

FIG. 1 is a process profile schematic diagram according to a specific embodiment of the present invention, which shows residues generated after performing an etching step for forming a dual damascene opening. It should be noted that the dual damascene opening shown in FIG. 1 is only an example for interpreting the present invention, the present invention is not limited to the dual damascene opening, but can be, for example, an via opening or an opening of other shape.

Referring to FIG. 1, a substrate 110 of a semiconductor wafer is first provided. A plurality of step of a process for manufacturing a semiconductor are performed on the substrate 110 to form a desired semiconductor assembly. As shown in the figure, a metal connection layer 120 preferably comprises copper, aluminum, tungsten, cobalt, tantalum, and the like. Then, an etching stopping layer 130 is selectively formed as a buffer layer before subsequent etching and opening of the metal connection layer 120, which can be configured to determine the time at which the etching ends, thus facilitating the fabrication of the damascene opening. The etching stopping layer 130 preferably comprises aluminum oxide, silicon carbonitride, silicon dioxide, and/or other common materials.

Then, a Low-k dielectric layer 140 is formed, which is generally a dielectric material layer having a low dielectric constant (less than 3.5). The Low-k dielectric layer 140 preferably comprises carbon-doped silicon oxide and other similar materials, and the forming method of the Low-k dielectric layer comprises spin coating, chemical vapor deposition, or other similar deposition processes. Then, an anti-reflection layer 150 is selectively formed on the Low-k dielectric layer 140, which helps to improve the effect of a lithography process during subsequent etching. The anti-reflection layer 150 preferably comprises a carbon or oxygen material, such as silicon dioxide. Then, a metal shielding layer 160 is formed on the anti-reflection layer 150. The metal shielding layer 160 can be formed by, for example, titanium, titanium nitride, tantalum nitride or similar metals.

Then, the etching process is performed to form an opening 170 which exposes the underlying metal connection layer 120. According to the specific embodiment shown in FIG. 1, the opening 170 is a damascene opening comprising a via opening 172 and a trench opening 174. Generally, the via opening 172 is a columnar opening, and the trench opening 174 is a linear opening which is connected to a plurality of via openings 172. Those with general knowledge in related technical field can understand that there are various different methods available to produce the damascene opening, so details are not repeated herein. However, it should be noted that the manufacturing process of the damascene opening 170 is not limited in the present invention. Generally, the via opening 172 and the trench opening 174 are preferably formed by a dry etching technology, such as plasma etching, and the etching gas is tetrafluoromethane (CF4), octafluorocyclobutane (C4F8) or other similar gases.

In the etching process, trace metal, organic matter or inorganic matter can be formed and distributed on the surface of the inner wall of the opening 170 to form residual by-products 180, 182 and 184 after etching. As shown in FIG. 1, according to the specific embodiment, the residual by-product 180 after etching can be, for example, a metal fluoride (such as titanium fluoride); the residual by-product 182 after etching formed on the side wall can be, for example, an organic polymer residue; and the residual by-product 184 after etching formed on the exposed surface of the metal connection layer 120 can be, for example, a copper-containing residue (such as copper, copper oxide and copper fluoride), a tungsten-containing residue, a cobalt-containing residue or similar substances. It should be noted that the residual components are only examples and may be different along with different materials of the metal connection layer 120, the etching stopping layer 130, the Low-k dielectric layer 140, the anti-reflection layer 150, the metal shielding layer 160, the etching gases and the like.

These residues have adverse effects on the subsequent process and the finally generated integrated circuit. For example, the residual by-product 184 after etching on the surface of the metal connection layer 120 may corrode the metal connection layer 120 and becomes a barrier between the metal subsequently filled in the opening 170 and the metal connection layer 120 so as to increase the contact resistance between two metal layers. On the other hand, the residual by-product 180 after etching may pollute other subsequently formed structural layers, and the residual by-product 182 after etching may increase the dielectric constant of an inline structure and influence the reliability of the inline structure.

### Example 1

A cleaning solution in the present invention is utilized to carry out the cleaning process so as to effectively remove residues. According to an Example 1 of the present invention, the cleaning solution comprises a first agent, a second agent and water; the first agent is configured to chelate residual metals on a semiconductor wafer; and the second agent has a solubility of 35 g/100 ml to 45 g/100 ml in water with a pH-value greater than 6 and less than 7 at 20° C., and has an acid dissociation constant between 7 and 8 at 20° C. According to the present invention, the metal chelating ability of the selected first agent is greater than that of the second agent. The second agent is mainly configured to maintain the pH-value of the cleaning solution between 6.5 and 8.8 at 20° C. to 70° C., preferably between 7.0 and 8.5 at 30° C. to 70° C., and particularly between 7.2 and 8.2 at 50° C. to 70° C., thus maintaining the metal chelating ability of the first agent. According to a preferred example, the second agent is a agent which is friendly to the biological environment. For example, the first agent is preferably aminopolycarboxylic acid, and the second agent is preferably N-substituted aminosulfonic acid. According to a more preferred example, the first agent comprises trans-1,2-Diaminocyclohexane-N,N,N′,N′-tetraacetic Acid (CyDTA), and the second agent comprises N-2-Hydroxyethylpiperazine-N′-2-ethanesulfonic Acid(HEPES). According to a more preferred example, the content of the first agent is 0.05 to 4 wt %, more preferably 0.2 to 1 wt % of the cleaning solution; and the content of the second agent is 0.1 to 5 wt %, more preferably 0.5 to 2 wt % of the cleaning solution. According to a more preferred example, the content of the first agent is higher than that of the second agent. According to the present invention, the content is based on the total weight of the cleaning solution.

### Example 2

The cleaning solution in the present invention can further comprise a third agent besides the first agent, the second agent and water; the third agent is configured to oxidize residues to be removed on the semiconductor wafer. For example, the third agent is preferably 4-Methylmorpholine N-oxide. The third agent preferably accounts for 3 to 30 wt %, more preferably 3 to 20 wt %, specially preferably 5 to 15 wt %, and more specially preferably 10 to 15 wt % of the cleaning solution. According to a preferred example, the second agent is N-2-Hydroxyethylpiperazine-N′-2-ethanesulfonic Acid (HEPES), and the third agent is 4-Methylmorpholine N-oxide, so that the structure of the second agent can be stabilized, and the pH-value buffer function effect of the second agent is improved. According to a preferred example, the weight content of the third agent is greater than the total weight content of the first agent and the second agent.

### Example 3

The cleaning solution in the present invention can further comprise a fourth agent besides the first agent, the second agent and water or the third agent; the fourth agent has an acid dissociation constant between 9.2 and 10 at 20° C. One of the main functions of the fourth agent is to assist the second agent to maintain the cleaning solution in the pH-value range. According to a preferred example, the fourth agent comprises ethanolamine or methyl monoethanolamine. According to a preferred example, the content of the fourth agent is 1 to 10 wt % of the cleaning solution; and according to a special preferred example, the content of the fourth agent is 1 to 5 wt % of the cleaning solution. According to a preferred example, the weight content of the fourth agent is less than that of the third agent.

### Example 4

The cleaning solution in the present invention can further comprise a fifth agent besides the first agent, the second agent, water, the third agent or the fourth agent. The fifth agent is configured to reduce the third agent which loses oxidizing ability. According to a preferred example, the fifth agent is added after the cleaning solution cleans at least one semiconductor wafer. The fifth agent is preferably hydrogen peroxide. In a preferred embodiment, the fifth agent includes hydrogen peroxide in an amount of 0.5 wt % to 30 wt % of the cleaning solution. In a preferred example, the fifth agent includes hydrogen peroxide in an amount of 0.5 wt % to 2 wt % of the cleaning solution. In a preferred example, the fifth agent includes hydrogen peroxide in an amount of 14 wt % to 17 wt % of the cleaning solution.

It should be noted that the agents in the present invention may have other functions besides the abovementioned functions. After the cleaning process is performed, the residual by-products 180, 182 and 184 after etching are removed, and then the subsequent process is performed to form a barrier layer and a conductive material (not shown in the figure) in the opening 170, which is a technology known by those with general knowledge in related technical field, so it is not repeated herein.

The cleaning solution in the present invention is to selectively remove various metals or organic and/or inorganic residues formed after etching through a proper formula. Therefore, the cleaning solution in the present invention can be applied to other semiconductor processes which may generate organic and/or inorganic residues, such as but not limited to a double-damascene process, a single-damascene process and/or other processes for etching Low-k materials in a dry etching mode.

The present invention also discloses a method for cleaning the semiconductor wafer through the cleaning solution. The method comprises the following steps: providing the cleaning solution in the present invention; making a first semiconductor wafer contact with the cleaning solution; and making the cleaning solution which makes contact with the first semiconductor wafer contact with an n^{th} semiconductor wafer which is different from the first semiconductor wafer, wherein the n^{th} semiconductor wafer makes contact with the cleaning solution which makes contact with an (n−1)^{th} semiconductor wafer, and n is a positive integer which is more than 1. For example, n−1 can be 2, and also can be 2,000, 3,000, 4,000, 5,000 or more than 6,000. In other words, after cleaning one semiconductor wafer, the cleaning solution can be reused for cleaning a plurality of wafers without losing efficiency. In various examples, the cleaning solution achieves the cleaning of at least 2,000 pcs, 3,000 pcs, 4,000 pcs, 5,000 pcs or 6,000 pcs. The same cleaning solution can be used for at least 1 h, 6 h, 12 h, 24 h, 30 h, 36 h, 48 h or even 72 h in terms of time.

In the cleaning method of the present invention, the semiconductor wafer can make contact with the cleaning solution in any proper mode, such as soaking the semiconductor wafer in the cleaning solution, or spraying the cleaning solution to wash the semiconductor wafer. In addition, the cleaning method of the present invention can not only be used for cleaning a single wafer at one time, but also can clean a plurality of wafers at one time. The temperature of the cleaning solution and the cleaning time are related to the residual materials to be removed, and the optimal time and temperature conditions can be found through experiments or experience. For example, the temperature of the cleaning solution is preferably about 20 to 70° C., or 20 to 50° C., or 30 to 40° C., or 30 to 50° C., or 50 to 70° C., and the contact time of each wafer is preferably about 0.5 to 30 min, or about 1 to 3 min.

Preferred embodiments of the present invention also contain other suitable components in addition to the aforesaid components. Although preferred embodiments of the present invention have been disclosed herein, it should be understood that the foregoing embodiments and technical features are provided as examples only and are not intended to limit the present invention. Various changes and substitutions can be made by those skilled in the art without departing from the invention. Accordingly, the present invention should be construed broadly to cover all such changes, modifications and alternative embodiments within the spirit and scope of the appended claims hereinafter.

1. A semiconductor wafer cleaning solution comprising:
a first agent, configured to chelate residual metals on a semiconductor wafer;
a second agent, which has a solubility of 35 g/100 ml to 45 g/100 ml in water with a pH-value greater than 6 and less than 7 at 20° C., and has an acid dissociation constant between 7 and 8 at 20° C.; and
water,
wherein the pH-value of the cleaning solution is maintained in the range of 6.5 to 8.8 at 20° C. to 70° C., and in the cleaning solution, a metal chelating ability of the first agent is greater than that of the second agent.

2. The semiconductor wafer cleaning solution according to claim 1, wherein the semiconductor wafer comprises a metal connection layer, a Low-k dielectric layer positioned above the metal connection layer, and a metal shielding layer positioned above the Low-k dielectric layer; each of the Low-k dielectric layer and the metal shielding layer is provided with an opening for exposing the metal connection layer; and the semiconductor wafer cleaning solution is used for removing objects to be moved formed in the openings.

3. The semiconductor wafer cleaning solution according to claim 1, wherein the first agent comprises aminopolycarboxylic acid, and the second agent comprises N-substituted aminosulfonic acid.

4. The semiconductor wafer cleaning solution according to claim 1, wherein the content of the first agent is 0.05 to 4 wt % of the cleaning solution, and the content of the second agent is 0.1 to 5 wt % of the cleaning solution.

5. The semiconductor wafer cleaning solution according to claim 1, wherein the first agent comprises trans-1,2-Diaminocyclohexane-N,N,N′,N′-tetraacetic Acid (CyDTA); and the second agent comprises N-2-Hydroxyethylpiperazine-N′-2-ethanesulfonic Acid(HEPES).

6. The semiconductor wafer cleaning solution according to claim 1, wherein the semiconductor wafer cleaning solution further comprises a third agent which is configured to oxidize the object to be moved on the semiconductor wafer.

7. The semiconductor wafer cleaning solution according to claim 6, wherein the third agent comprises 4-Methylmorpholine N-oxide.

8. The semiconductor wafer cleaning solution according to claim 6, wherein the content of the third agent is 3 to 30 wt % of the cleaning solution.

9. The semiconductor wafer cleaning solution according to claim 1, wherein the semiconductor wafer cleaning solution further comprises a fourth agent; and the fourth agent has an acid dissociation constant between 9.2 and 10 at 20° C.

10. The semiconductor wafer cleaning solution according to claim 9, wherein the fourth agent includes ethanolamine or methyl monoethanolamine.

11. The semiconductor wafer cleaning solution according to claim 9, wherein the content of the fourth agent is 1 to 10 wt % of the cleaning solution.

12. The semiconductor wafer cleaning solution according to claim 6, wherein the semiconductor wafer cleaning solution further comprises a fifth agent which is configured to reduce the third agent which loses oxidizing ability.

13. The semiconductor wafer cleaning solution according to claim 12, wherein the fifth agent comprises hydrogen peroxide.

14. The semiconductor wafer cleaning solution according to claim 12, wherein the content of the fifth agent is 0.5 to 30 wt % of the cleaning solution.

15. A semiconductor wafer cleaning solution comprising:
a first agent which comprises trans-1,2-Diaminocyclohexane-N,N,N′,N′-tetraacetic Acid Monohydrate (CyDTA) accounting for 0.05 to 4 wt % of the cleaning solution;
a second agent which comprises N-2-Hydroxyethylpiperazine-N′-2-ethanesulfonic Acid (HEPES) accounting for 0.1 to 5 wt % of the cleaning solution;
a third agent which comprises 4-Methylmorpholine N-oxide accounting for 3 to 30 wt % of the cleaning solution; and
water.

16. The semiconductor wafer cleaning solution according to claim 15, wherein the semiconductor wafer cleaning solution further comprises a fourth agent which comprises ethanolamine or methyl monoethanolamine accounting for 1-10 wt % of the cleaning solution.

17. The semiconductor wafer cleaning solution according to claim 15, wherein the semiconductor wafer cleaning solution further comprises a fifth agent which comprises hydrogen peroxide accounting for 0.5 to 30 wt % of the cleaning solution.

18. A semiconductor wafer cleaning method, comprising:
step A: providing a semiconductor wafer cleaning solution;
step B: making a first semiconductor wafer contact with the cleaning solution; and
step C: making the cleaning solution which makes contact with the first semiconductor wafer contact with an n^{th} semiconductor wafer which is different from the first semiconductor wafer, the n^{th} semiconductor wafer making contact with the cleaning solution which makes contact with an (n−1)^{th} semiconductor wafer, and n−1 being a positive integer greater than 1,
wherein the semiconductor wafer cleaning solution includes: (i) a first agent, configured to chelate residual metals on a semiconductor wafer; (ii) a second agent, which has a solubility of 35 g/100 ml to 45 g/100 ml in water with a pH-value greater than 6 and less than 7 at 20° C., and has an acid dissociation constant between 7 and 8 at 20° C.; and (iii) water; and the pH-value of the cleaning solution is maintained in the range of 6.5 to 8.8 at 20° C. to 70° C., and in the cleaning solution, a metal chelating ability of the first agent is greater than that of the second agent.

19. The semiconductor wafer cleaning method according to claim 18, wherein the method comprises a step D of repeating the step C until n−1 is at least 2,000.

20. The semiconductor wafer cleaning method according to claim 18, wherein the semiconductor wafer cleaning solution further comprises a third agent which is configured to oxidize the object to be moved on the semiconductor wafer; and a fourth agent having an acid dissociation constant between 9.2 and 10 at 20° C.

21. The semiconductor wafer cleaning method according to claim 18, wherein the semiconductor wafer comprises a metal connection layer, a Low-k dielectric layer positioned above the metal connection layer, and a metal shielding layer positioned above the Low-k dielectric layer; each of the Low-k dielectric layer and the metal shielding layer is provided with an opening for exposing the metal connection layer; and the semiconductor wafer cleaning solution is used for removing objects to be moved formed in the openings.

22. The semiconductor wafer cleaning method according to claim 20, wherein the semiconductor wafer cleaning solution further comprises a fifth agent which is added in the step C to reduce the third agent which loses oxidizing ability.

23. The semiconductor wafer cleaning method according to claim 22, wherein the fifth agent comprises hydrogen peroxide.

24. The semiconductor wafer cleaning method according to claim 23, wherein the content of the fifth agent is 0.5 to 30 wt % of the cleaning solution.
